(19) United States
(12) Patent Application Publication
(10) Pub. No.: US 2013/0160850 A1
(43) Pub. Date: Jun. 27, 2013

(54) BLAZED GRATING FOR SOLAR ENERGY CONCENTRATION

(71) Applicant: Prism Solar Technologies Incorporated, Highland, NY (US)

(72) Inventors: Eric D. Aspnes, Tucson, AZ (US); Jose E. Castillo, Tucson, AZ (US); Ryan D. Courreges, Tucson, AZ (US); Paul S. Hauser, Tucson, AZ (US); Glenn Rosenberg, Tucson, AZ (US); Jeffrey W. Rosenberg, Tucson, AZ (US)

(73) Assignee: Prism Solar Technologies Incorporated, Highland, NY (US)

(21) Appl. No.: 13/708,160

(22) Filed: Dec. 7, 2012

Related U.S. Application Data
(60) Provisional application No. 61/569,097, filed on Dec. 9, 2011.

(51) Int. Cl. H01L 31/0232

(52) U.S. Cl. CPC H01L 31/02327
USPC 136/259

(57) ABSTRACT

A solar concentrator having a photovoltaic cell in optical contact with a cover. A blazed grating is provided adjacent to and co-planar with the photovoltaic cell for preferentially diffracting light that does not directly intercept the photovoltaic cell toward the photovoltaic cell via total internal reflection in the cover.

### RELATED APPLICATIONS

This application claims priority to U.S. Provisional Application No. 61/569,097, filed on Dec. 9, 2011, entitled “Blazed Grating for Solar Energy Concentration”, the contents of which are incorporated herein by reference.

### TECHNICAL FIELD

The present invention relates to photo-voltaic conversion of solar radiation and, in particular, to the use of blazed gratings in planar sun-light concentrators.

### BACKGROUND ART

Solar energy will satisfy an important part of future energy needs. While the need in solar energy output has grown dramatically in recent years, the total output from all solar installations worldwide still remains around 7 GW, which is only a tiny fraction of the world's energy requirement. High material and manufacturing costs, low solar module efficiency, and shortage of refined silicon limit the scale of solar power development required to effectively compete with the use of coal and liquid fossil fuels.

The key issue currently faced by the solar industry is how to reduce system cost. The main-stream technologies that are being explored to improve the cost-per-kilowatt of solar power are directed to (i) improving the efficiency of a solar cell that comprises solar modules, and (ii) delivering greater amounts of solar radiation onto the solar cell. In particular, these technologies include developing thin-film, polymer, and dye-sensitized photovoltaic (PV) cells to replace expensive semiconductor material based solar cells, the use high-efficiency smaller-area photovoltaic devices, and implementation of low-cost collectors and concentrators of solar energy.

While the reduction of use of semiconductor-based solar cells is showing great promise, for example, in central power station applications, it remains disadvantageous for residential applications due to the form factor and significantly higher initial costs. Indeed, today's residential solar arrays are typically fabricated with silicon photovoltaic cells, and the silicon material constitutes the major cost of the module. Therefore techniques that can reduce the amount of silicon used in the module without reducing output power will lower the cost of the modules.

The use of devices adapted to concentrate solar radiation on a solar cell is one of such techniques. Various light concentrators have been disclosed in related art, for example a compound parabolic concentrator (CPC); a planar concentrator such as, for example, a holographic planar concentrator (HPC) including a planar highly transparent plate and a holographically-recorded optical element mounted on its surface; and a spectrum-splitting concentrator (SSC) that includes multiple, single junction PV cells that are separately optimized for high efficiency operation in respectively-corresponding distinct spectral bands. A conventionally-used HPC is deficient in that the collection angle, within which the incident solar light is diffracted to illuminate the solar cell, is limited to about 45 degrees. Production of a typical SSC, on the other hand, requires the use of complex fabrication techniques.

### BRIEF DESCRIPTION OF THE DRAWINGS

FIG. 1 is a schematic of a holographic planar concentrator.

FIG. 2A shows an embodiment of a holographic spectrum-splitting device.

FIG. 2B shows an alternative embodiment of a holographic spectrum-splitting device.

FIG. 3A is a schematic of an embodiment of a planar solar concentrator employing a monofacial PV-cell using a co-planar blazed grating structure according to an embodiment of the invention.

FIG. 3B shows an example of structure of a layer containing a blazed diffractive grating, according to an embodiment of the invention.

FIG. 3C is an concentrator embodiment including three portions, each of which is configured in a fashion similar to that of the embodiment of FIG. 3A.

FIG. 4 is a top view of the embodiment of FIG. 3

### DETAILED DESCRIPTION OF PREFERRED EMBODIMENTS

Embodiments of the present invention provide a system and method for delivering solar radiation towards the photovoltaic (PV) cell with the use of a diffractive device employing a blazed grating that is optionally coplanar with the PV-cell. Such grating lends itself to being produced in a stamped roll-to-roll process.

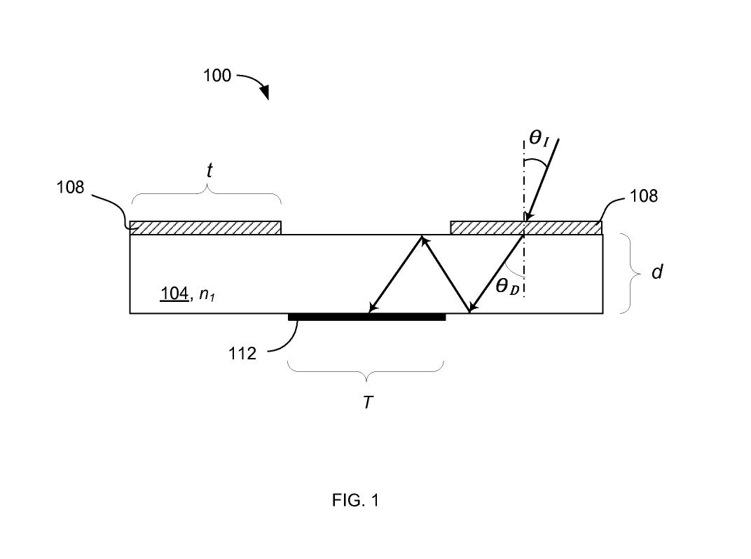

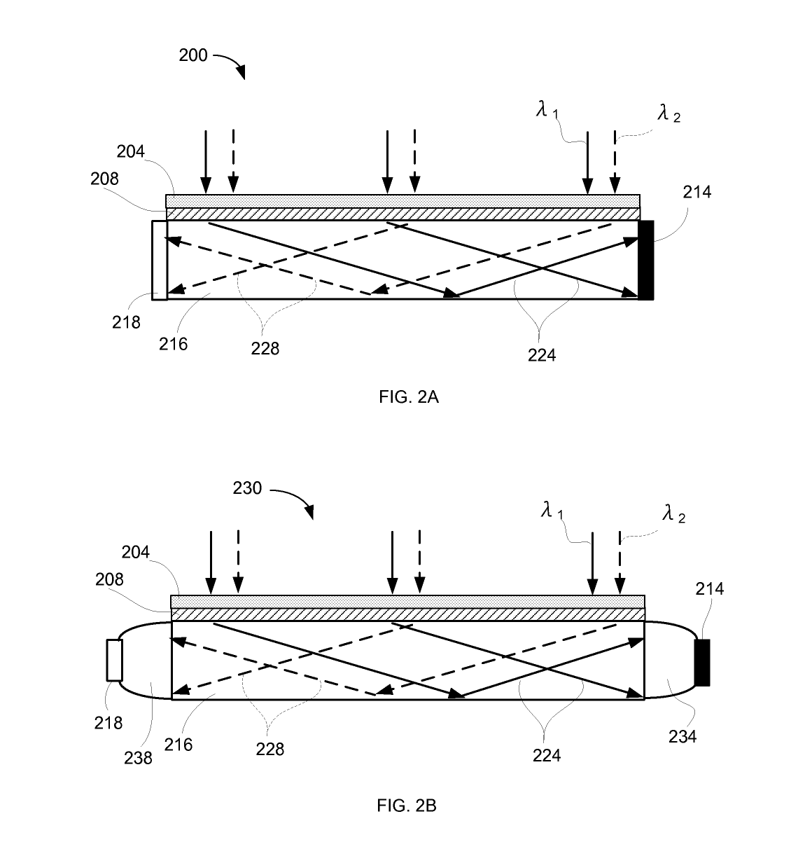

Typical devices currently used for concentration of solar radiation for the purposes of PV-conversion are shown schematically in FIGS. 1, 2A, and 2B. For example, an HPC 100 of FIG. 1, shown in a cross-sectional view, typically includes a highly-transparent planar substrate (or cover made of, e.g., glass) 104 of thickness d (such as, for example, substrate made of glass or appropriate polymeric material having the refractive index n₁) at least one diffractive structure 108, having width t, at a surface of the substrate 104. Such diffractive structure may include, for example, a holographic optical film (such as gelatin-on-PET film stack) in which a plurality of multiplexed diffraction gratings have been recorded with the use of laser light. The diffractive structure 108 can be optionally capped with a protective cover layer (not shown). The substrate 104 is typically cooperated with a solar-energy-collecting device 112 such as a PV cell. The diffractive structures 108 diffract wavelengths usable by the PV cell 112, while allowing the light at unusable wavelength to pass through, substantially unabsorbed. The usable energy is guided via the total internal reflection at the glass/air or glass/cover interface to strings of solar cells, resulting in up to a 3× concentration of solar energy per unit area of PV material.

Further in reference to FIG. 1, the PV cell 112 of width T is juxtaposed with the second surface of the substrate 104 in opposition to the diffractive structures 108 and in such orientation that ambient (sun-) light I, incident onto the structure 108 at an angle θ₁, is diffracted at an angle θ_{D} onto the cell 112 either directly or upon multiple reflections within the substrate 104. To estimate the range of incident angles that would produce the diffracted light intersecting the surface of the PV cell 112 for different parameters of the HPC 100 such as substrate thickness, the displacement of the PV cell 112 with respect to the edge of the grating 108, other geometrical parameters one can use the grating equation. For example, for a glass substrate 104 and when t=T=d, the range of incident angles (the collection angle) at which the cell 112 is illuminated is about 45 degrees. When t=2T=2d, the collection angle is reduced to about 38 degrees. The angular range within which the corresponding diffracted light is produced is about 10° to 15° for most of the wavelengths. However, the angle-wavelength matching can be used to extend this range for different portions of the available spectral bandwidth of the HPC 100.

The increase in PV-conversion efficiency, in comparison with a use of a conventional PV-cell, is also achieved by using multiple junction cells that create electron-hole pairs at the expense of energy of incident light over a wider spectral range than a single junction cell. The use of a holographic grating with such spectrum-splitting devices (SSD) also offers some advantages. The hologram is usually designed to diffract light within a specific spectral band in a desired direction (for example, towards one PV-cell) and be multiplexed with another hologram that diffracts light of different wavelength in another direction (for example, towards another PV-cell). One example of such holographic SSD 200, shown in FIG. 2A, includes two diffractive structures 204 and 208 such as diffractive gratings, holographically-recorded in a medium that usually includes gelatin-based material. The gratings 204 and 208 are cascaded at a surface 212 of the substrate 216 (i.e., at the input of the SSD 200) and that diffract light of different wavelengths. For example, the upper hologram 204 diffracts light at wavelength λ₁ longer than wavelength λ₂ diffracted by the hologram 208. Two PV-cells, respectively-corresponding to the holograms 204 and 208—a long-wavelength PV cell 214 and a short-wavelength PV-cell 218—are positioned transversely with respect to the holograms 204, 208 (as shown, at side facets of the substrate 216). Directionally-diffracted towards target PV-cells light 224, 228 reaches the PV-cells via reflections off the surfaces of the substrate 216. A simple light-concentrating reflector can additionally be used. A similar SSD 230, upgraded with cylindrical parabolic reflectors 234, 238 that guide the diffracted light towards target PV-cells, is depicted in FIG. 2B. In both cases, the collection angle is determined by geometry of the system and the diffraction characteristics of the holograms.

The use of conventional volume holograms recorded in, for example, dichromated gelatin can result in certain packaging challenges. Because the gelatin-based material is hydrophilic, changes in humidity levels of the ambient environment affect the optical and/or geometrical parameters of the diffraction gratings recorded in such material (due to, for example, index changes and/or swelling of the material that has absorbed moisture, which would change the geometry of the hologram). Consequently, the operation of the diffraction gratings of the light-concentrating embodiments of FIGS. 1, 2A, and 2B is affected and with it is affected the PV conversion efficiency. These challenges can be overcome through the use of various novel packaging techniques, e.g., encapsulating gelatin based holograms in moisture impermeable encapsulant layers either coincident with or prior to assembly of the holographic layers to the solar cell assembly. Novel encapsulation techniques are disclosed on other co-owned applications.

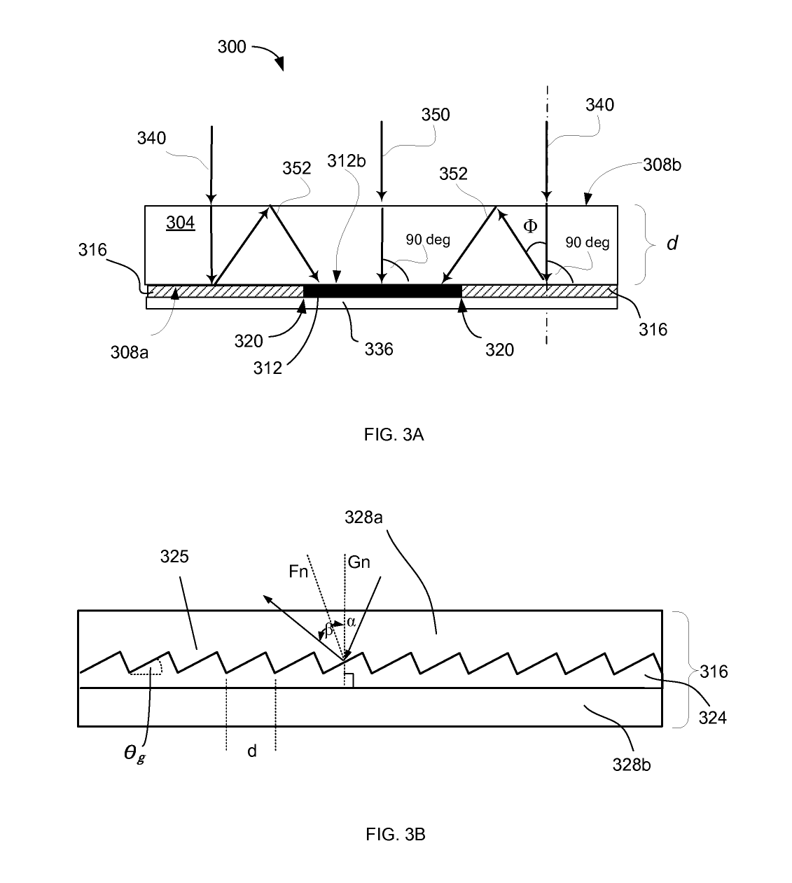

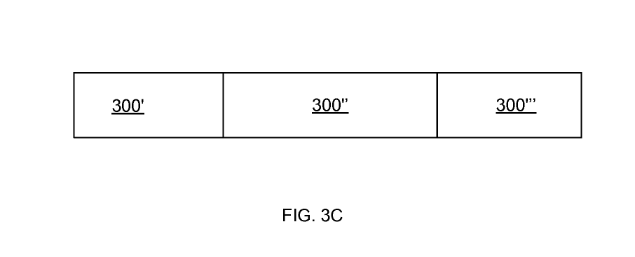

Embodiments of the invention achieve improved solar concentration while overcoming the environmental challenges inherent in the use of gelatin based holograms through the use of stamped metal blazed gratings and other robust diffractive structures. FIG. 3 is a schematic of a solar cell or concentrator according to an embodiment of the invention. The embodiment of FIG. 3 incorporates a plurality of metal blazed grating holograms arranged to diffract light not directly intercepted by a PV-cell onto a PV-cell. In the embodiment of FIG. 3A, a solar cell 300 includes a cover layer 304 such as a glass or plastic plane-parallel plate of thickness d. In certain embodiments, d is substantially equal to 1.1 mm. In other embodiments, d is substantially equal to 1.8 mm. In certain embodiments, cover 304 is glass, having an index of refraction of about 1.5. Acceptable materials for cover 304 include, but are not limited to, glass, sapphire, acrylic, polycarbonate, polystyrene, or Cyclic Olefin Copolymer (“COC”). Cover 304 is substantially transparent in the visible and IR spectra, and has a substantially uniform spatial distribution of its refractive index. On a first side 308a of cover 304 is disposed, in an adjoining fashion, both a monofacial PV-cell 312 and layer 316, such that both PV-cell 312 and layer 316 are substantially co-planar and in optical contact with cover 304. The monofacial PV-cell 312 is configured to photo-voltaically convert solar energy received at its front or top facing surface, i.e., the surface in contact and facing toward cover 304. As shown in the side view of FIG. 3A, the PV-cell 312 has two neighboring layers 316, one on each side of the PV-cell 312, located in physical contact with one another along the seams 320. In an alternative embodiment (not shown), the PV-cell 312 and at least one layer 316 may be separated from one another along the surface 308a such that a gap between the PV-cell 312 and the layer 316 in question defines a portion of the surface 308a that is not covered by either the PV-cell 312 or the layer 316. In another alternative embodiment (not shown), only a single layer 316 is placed in proximity to the PV-cell 312 on one of its sides. Both sides 308a,b of cover 304 optionally have additional thin film layers such as anti-reflective or hard coatings that have been omitted for clarity.

FIG. 3B shows a magnified, not-to-scale, cross-sectional diagram of layer 316 in greater detail. Layer 316 includes a blazed grating 324. In certain embodiments, blazed grating 324 is fabricated by stamping or rolling silver, gold, aluminum or other foil with a master replication tool on a roll to roll process. The master replication tool is fabricated according to conventional processes, e.g., by diamond scribing a steel or nickel cylinder. Layer 316 includes an encapsulant layer 328a, which serves to adhere grating 324 to cover 304 and provide optical contact thereto. Acceptable materials for encapsulant 328a include, but are not limited to, silicone, EVA, or other ionomers such as Surlyn available from DuPont & Co., Wilmington, Del. The material for encapsulant 328a is preferentially chosen to index match (i.e., establish optical contact) grating 324 to cover 304 so as to minimize loses due to Fresnel reflections within the concentrator. Layer 316 optionally includes a lower encapsulant layer 328b, which adheres grating 324 to a backsheet, 336. In certain embodiments, backsheet 336 is a moisture impermeable, relatively rigid (but still flexible) substrate layer of a plastic material such as PET. In certain embodiments, lower encapsulant layer 328b extends into and is a unitary structure with backsheet 336.

As is shown in FIG. 3B, blazed grating 324 is characterized by an array of angled rectangular facets 325, each having a short dimension the extent of which is visible in the plane of FIG. 3B, and a relatively much longer long dimension running normal to the plane of FIG. 3b. The grating shape of FIG. 3B may be referred to as a “sawtooth”. The grating 324 has a “blaze direction” or “blaze arrow”, which is defined by the sign of the angle between the grating normal Gn and the grating facet normal Fₙ. In the case of the grating of FIG. 3B, the blaze direction is to the left. As is known in the art, a blazed grating is designed to concentrate diffracted light of a particular wavelength into a particular angle corresponding to a particular diffractional order. This is accomplished by optimizing the period of the grating and the blaze angle. Facets 325 are inclined at an angle θ_{g} (the blaze angle) with respect to the plane of the grating, which results in the facet normals making an angle of θ_{g} with respect to the surface normal of the plane of the grating Gₙ. Additionally, blazed grating is characterized by a grating period d. As is known in the art, for a given diffractional order m and wavelength λ, light incident on the grating at an angle α (measured with respect to the grating normal Gₙ) will be diffracted along angle β according to the relationship: mλ=d(sin(α)+sin(β)). In order to maximize efficiency, the amount of light concentrated into the designed-for diffractional order, the blaze angle θ_{g} is chosen such that the angled facet acts as a specular reflector as to the incident and diffracted rays. In other words, to maximize efficiency, the blaze angle θ_{g} is chosen such that the angle of the incident ray measured as to the facet normal (Fn in FIG. 3B) is equal (but opposite in sign) to the angle of the diffracted ray measured as to the facet normal. This condition occurs when θg=(α+β)/2.

In certain embodiments of the invention, blazed grating 324 is optimized to diffract light arriving at normal incidence to the plane of the grating (i.e., along Gₙ) toward PV cell 312 at such an angle that the diffracted light undergoes total internal reflection in cover 304. In one embodiment, the wavelength for which performance of grating 324 is optimized is the wavelength of peak spectral response for PV cell 312. In another embodiment, the wavelength for which performance of grating 324 is optimized is the wavelength at which PV cell 312 has its greatest photovoltaic conversion rate given the expected installation arrangement of the solar module. In one embodiment, the optimization wavelength selected is about 780 nm in air. In certain embodiments, blazed grating 324 is configured such that the surface normals of facets 325 point toward PV cell 312. This has the advantage of not only increasing the diffraction efficiency of the grating in the toward the cell direction, but also, to allow for specular reflection from the plane of the grating (so-called “zero order diffraction”) of light outside of the optimized wavelengths to occur toward PV cell 312. In one embodiment, the blaze angle selected is about 25 degrees, and the grating period is about 650 nm. In this configuration and for 780 nm, β, the diffracted angle, is about 53 degrees, which is well above the critical angle for a glass cover 304 having an index of about 1.5.

Although the embodiment described above with reference to FIG. 3B is a stamped, ruled, metal grating, this is not a requirement. Volumetric and/or phase gratings, such as those holographically recorded in dichromated gelatin are acceptable and should be considered within the scope of the invention. Additionally, gratings of configurations other than sawtooth gratings are acceptable, for example, symmetrical triangular, lamellar, sinusoidal and/or trapezoidal gratings.

In further reference to FIGS. 3A and 3B, the grating structure 324 is appropriately arranged such that, upon interaction with the grating structure, the incident light 340 within the spectral region of interest diffracts towards the PV-cell 312 at an angle Φ (equivalent to angle β, described above) that does not change appreciably with the small variation of the angle of incidence of light 340. Angle Φ is a function of the wavelength of incoming light 340 and the geometry of the grating structure 324, and is chosen to be above the critical angle associated with the material of cover 304, such that the diffracted light 352 is further guided by total internal reflection towards the PV-cell 312 within the cover 304. Light 350, penetrating through the cover 304 directly towards the PV-cell 312, does not diffract. It is appreciated that a general embodiment of the concentrator may be configured as a multi-portion structure, where a single portion is configured in a fashion of the embodiment 300 of FIG. 3A. An example 370 of such multi-portion structure including three portions 300′, 300″, and 300″′ is shown schematically in FIG. 3C. Generally, different portions can have different extent of corresponding PV-cells and corresponding diffractive gratings. As shown in FIG. 3C, for example, the lateral extent of the portion 300″ is larger than lateral extent of either of the portions 300′ or 300″′. Multiple portions of the embodiment may optionally share the substrate (such as the cover 304 of FIGS. 3 A and B and the overlayer covering the corresponding diffraction gratings and the PV-cells, such as the backsheet 336.

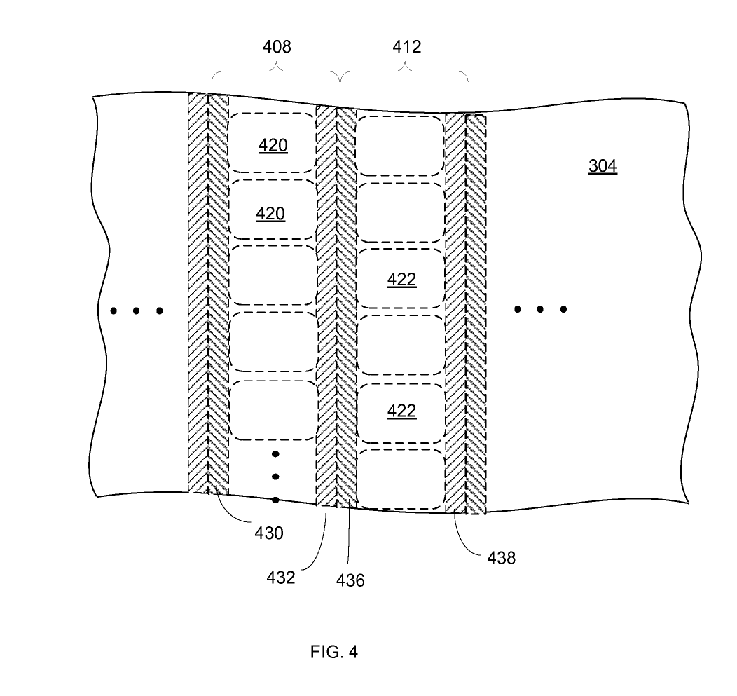

A top view of an array of PV cells (e.g., each cell being an embodiment 300) is schematically shown in FIG. 4. The embodiment of FIG. 4 is a multi-portion (or multi-period) embodiment and, as shown, includes two portions 408, 412. Additional portions or periods are not shown but indicated with three-point designators 416. Each of the portions or periods 408, 412 includes a corresponding monofacial PV-cell (420 or 422) that is surrounded by (and co-planar with) respectively-corresponding blazed grating layers (430, 432) or (436, 438) arranged to be co-planar with PV-cells 420, 422. Grating layers 430, 432, 436, 438 are reflective blazed gratings arranged in accordance with the structure described in reference to FIG. 3B. In the embodiment of FIG. 4, grating 430 and 432 are arranged with the facet normals (i.e., blaze directions or blaze arrows) of their respective gratings pointing toward PV-Cells 420. Likewise gratings 436 and 438 are arranged with the facet normals of their respective gratings pointing toward PV-Cells 422. It is contemplated that an array of solar cells in the embodiment of FIG. 4 will be arranged and installed such that the daily direction of solar travel occurs parallel to the linear arrangement of cells 420 and 422, e.g., from the top of the page of FIG. 4 to the bottom or vice versa. In other words, it is contemplated that the direction of solar travel will be parallel to long dimension of the facets of the blazed grating 324 described above with respect to FIG. 3.

What is claimed is:

1. A solar concentrator comprising:
an optically transparent cover having a first surface and a second surface opposing the first surface;
a PV-cell affixed to said second surface and in substantial optical contact with said cover; and
a first reflective blazed grating disposed adjacent to said PV-cell, the first reflective blazed grating being configured such that light incident normally onto said first blazed grating through said cover is diffracted towards said PV-cell.

2. The concentrator of claim 1, wherein said first reflective blazed grating is configured such that normally incident light is diffracted into a first diffractional order, towards said PC-cell, at an angle above the critical angle of the material of the cover.

3. The concentrator of claim 1, wherein said first reflective blazed grating has a blaze direction pointing toward the PV-cell.

4. The concentrator of claim 1, wherein said first reflective blazed grating is optimized to diffract normally incident light of about 780 nm at an angle above the critical angle of a material having an index of about 1.5.

5. The concentrator of claim 1 wherein said first reflective blazed grating has a grating period of about 650 nm, and a blaze angle of about 25 degrees.

6. The concentrator of claim 1, wherein said first reflective blazed grating is a metallic, sawtooth grating.

7. The concentrator of claim 1, wherein said first reflective blazed grating is substantially co-planar with said PV-cell.

8. The concentrator of claim 1, further comprising an encapsulant layer disposed adjacent to said PV-cell, the encapsulant providing optical contact between said first reflective blazed grating and said cover.

9. The concentrator of claim 1, further comprising a second reflective blazed grating disposed adjacent to said PV-cell on an opposite side of said PV cell from said first reflective blazed grating, said second reflective blazed grating being configured such that light incident normally onto said second reflective blazed grating through the cover is diffracted towards the PV-cell.
